(19) United States
(12) Patent Application Publication
(10) Pub. No.: US 2008/0088894 A1
(43) Pub. Date: Apr. 17, 2008

(54) System for image color correction and method thereof

(76) Inventors: Te-Mei Wang, Hsin-Chu (TW); Fu-Chuan Tsai, Hsin-Chu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/826,210

(22) Filed: Jul. 13, 2007

(30) Foreign Application Priority Data
Oct. 17, 2006 (TW) 095138301

(51) Int. Cl. G03F 3/08

(52) U.S. Cl. 358/520; 358/518

(57) ABSTRACT

The present invention relates to a system for image color correction and a method thereof. The system for image color correction includes at least a color correction module, which can correct color values to be corrected to ideal color values for giving corrected color values. In addition, the system according to the present invention corrects the color values between the corrected and the uncorrected color values, and smoothen the lightness and color transition therebetween, so that the false-contour problem is not occurred in the image with corrected colors. The system according to the present invention can further include a color interpolation module and a lookup table. According to the lookup table, a plurality of corresponding output color values of a plurality of color values of an input image could be found. Thereby, complicated correction procedures described above can be reduced, and the speed of color correction is increased as well.

### FIELD OF THE INVENTION

The present invention relates generally to a correction system and a method thereof, and particularly to a system for image color correction and a method thereof.

### BACKGROUND OF THE INVENTION

Generally HSV system is applied for performing color detection and color correction. Please refer to FIG. 5. In the color detection part, the step S30 is executed first, which converts image data (with RGB color format) of an input image to first color data (with HSV color format). Next, the step S31 is executed to judge if the plurality of color values of the first color data of the input image is the plurality of color values of some specific colors. If not, then the step S32 is executed to convert the first color data of the input image to second color data (with RGB color format) and give an output image. In addition, the step S33 is executed for transmitting the output image to a display.

If the plurality of color values of the first color data of the input image is the plurality of color values of the specific colors, then the step S34 is executed to enter the color correction part, in which the image data (with RGB color format) is converted to third color data (with XYZ color format). Then the step S35 is executed to correct the plurality of color values of the judged specific colors to give the corrected third color data of the image, which is, in the step S36, converted to fourth color data (with RGB color format) to give a corrected output image. Finally, the step S33 is executed to transmit the corrected output image to the display. Besides, the input image can enter directly to the step S34 for performing color correction. Then, the corrected output image is transmitted to the display.

Though the prior art described above can be used to adjust a part of color values of images, the corrected images have the false-contour problem. Accordingly, the prior art cannot meet users' demands in practical exercise.

### SUMMARY

The purpose of the present invention is to provide a system for image color correction and a method thereof, which can correct a part of color values of an image, and the corrected image have no false-contour problem.

Another purpose of the present invention is to provide a system for image color correction and a method thereof, which uses a lookup table built in the system to perform directly color correction to the image for reducing complicated color conversion and correction procedures. Thereby, the speed of color correction is increased.

In order to achieve the purposes described above, the present invention provide a system for image color correction and a method thereof, which includes at least a color correction module including a first color conversion unit, a selection unit, a correction unit, a smoothening unit, and a second color conversion unit.

The method for image color correction first inputs an image to the first color conversion unit of the color correction module for converting color data of the image to first color data, and for transmitting said first color data to the selection unit. The selection unit selects a plurality of color values to be corrected from the first color data of the image, and transmits the plurality of color values to be corrected to the correction unit. The correction unit corrects the plurality of color values selected by selection unit to a plurality of corresponding ideal color values and gives a plurality of corrected color values, which is then transmitted to the smoothening unit. The smoothening unit corrects the color values between the plurality of corrected color values and the plurality of proximal uncorrected color values, and smoothens the lightness and color transition therebetween for giving corrected first color data of the image and transmitting it to the second color conversion unit. The second color conversion unit converts the corrected first color data of the image to second color data and outputs a corrected image.

The present invention further comprises a color interpolation module and a lookup table. The lookup table is built according to the color data of a group of sample images and the corresponding second color data generated by the method described above. While correcting colors of other images, find out the plurality of corresponding output color values of the plurality of color values for the color data of said other images according to the lookup table. When the plurality of corresponding output color values is not found, color interpolation operations are performed to the plurality of color values of the color data of the image described above for outputting corrected images.

### BRIEF DESCRIPTION OF THE DRAWINGS

FIG. 1 shows a schematic diagram of system architecture for image color correction according to a preferred embodiment of the present invention;

FIG. 2 shows a schematic diagram of system architecture for image color correction according to another preferred embodiment of the present invention;

FIG. 3 shows a flowchart of a method for image color correction according to a preferred embodiment of the present invention;

FIG. 4 shows a flowchart of a method for image color correction according to another preferred embodiment of the present invention; and

FIG. 5 shows a flowchart of a method for image color correction according to the prior art.

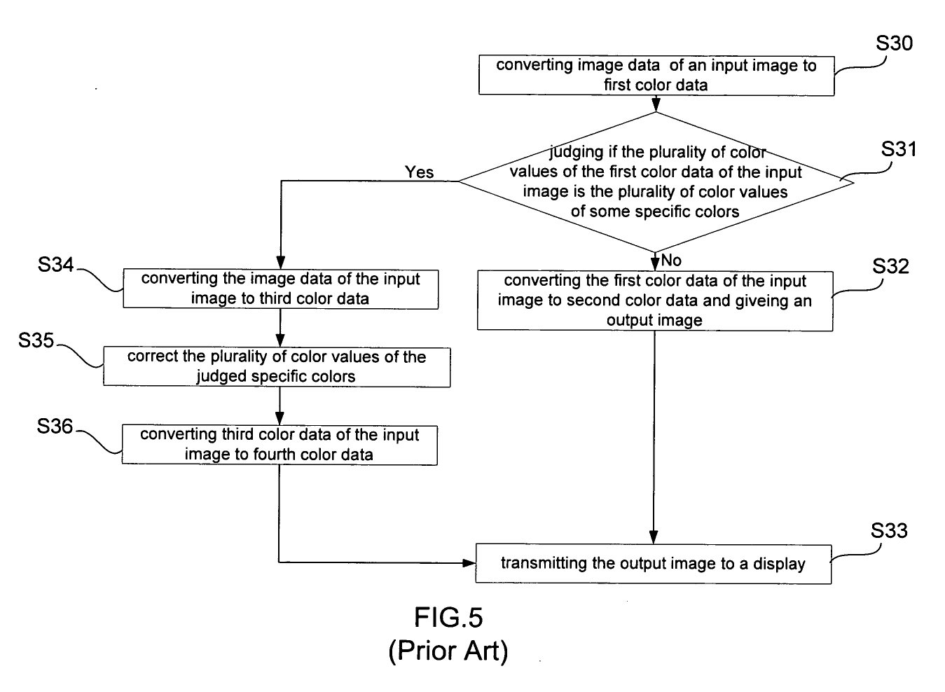

### DETAILED DESCRIPTION

In order to make the structure and characteristics as well as the effectiveness of the present invention to be further understood and recognized, the detailed description of the present invention is provided as follows along with preferred embodiments and accompanying figures.

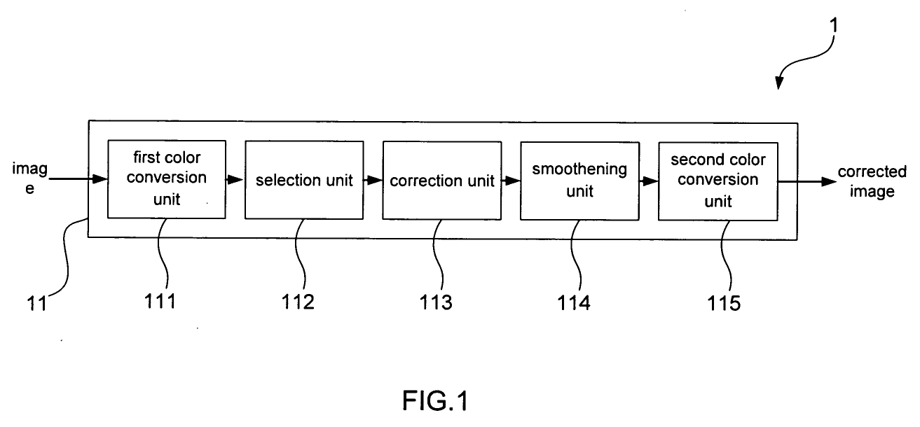

FIG. 1 shows a schematic diagram of system architecture for image color correction according to a preferred embodiment of the present invention. As shown in the figure, the system for image color correction 1 according to the present invention includes at least a color correction module 11, which includes a first color conversion unit 111, a selection unit 112, a correction unit 113, a smoothening unit 114, and a second color conversion unit 115.

The color correction module 11 receives an image, converts color data of the image to first color data by the first color conversion unit 111, and transmits the first color data of the image to the selection unit 112. The color data of the image is in the red-green-blue (RGB) color format. The color format of the first color data of the image can be chosen from the group consisting LCh, YUV, XYZ, Lab, or other color formats. The color data of the image includes a plurality of color values. Each of the color values includes a red value, a green value, and a blue value.

The selection unit 112 selects a plurality of color values to be corrected from the first color data of the image. The selection unit 112 first configures a color correction range, and judges if a plurality of color values of the first color data of the image are the color values to be corrected according to the color correction range. For example, when the first color data of the image is the LCh color format, i.e. lightness (L), chroma (C), and hue (h). The color correction range can be configured as: lightness being between 10 and 90, chroma being between 10 and 100, and hue, 0 and 76. According to the color correction range described above, it is judged that if the plurality of color values of the first color data of the image falls within the color correction range. When the color value falls in the color correction range, it is a color value to be corrected.

The correction unit 113 corrects the plurality of color values to be corrected selected by the selection unit 112 to a plurality of corresponding ideal color values. The correction method is to calculate a correction value between every color value to be corrected and the corresponding ideal color value. Then, according to the correction values, correct the color values to be corrected to the corresponding ideal color values for giving a plurality of corrected color values, which is further transmitted to the smoothening unit 114.

The smoothening unit 114 corrects a plurality of color values near the color selected by selection unit. First, the correction color values of the plurality of selected color values are calculated by correction unit. The smoothening unit calculates the relation of correction color values between selected color and neighbor colors. Then, according to the relation of correction color values, correct the plurality of color values neighbor selected colors. Next, smoothen the lightness and color transition therebetween for giving corrected first color data of the image and transmit it to the second color conversion unit 115 for converting colors.

The second color conversion unit 115 converts the first color data of the corrected image described above to second color data. The second color data of the image is in red-green-blue color format. Then a corrected image is outputted.

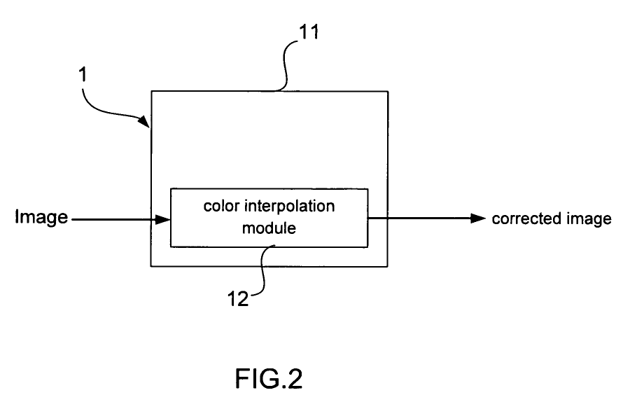

In FIG. 2, the system for image color correction 1 according to the present invention further includes a color interpolation module 12 and a lookup table. The lookup table is built according to the color data of a group of sample images and the corresponding second color data generated by the method described above. The lookup table includes a plurality of sets of input color index values and a plurality of sets of corresponding output color values. Each of the input color index value and the output color value include a red value, a green value and a blue value, respectively.

The color correction module 11 uses the lookup table and the color interpolation module 12. When an image is input, a plurality of color values for color data of the image is input to the lookup table for finding out a plurality of corresponding output color values, and consequently a corrected image can be output. Thereby, the complicated procedures described above can be omitted, and the speed of image color correction can be increased. When an image is input to the color correction module 11 and the plurality of color values for color data of the image is input to the lookup table, if the plurality of corresponding output color values cannot be found, the color interpolation module 12 performs color interpolation operations to the plurality of color values for the color data of the image according to the plurality of input color index values and the corresponding output color values of the lookup table for giving a plurality of corresponding output color values of the plurality of color values of the image. Finally, a corrected image is given.

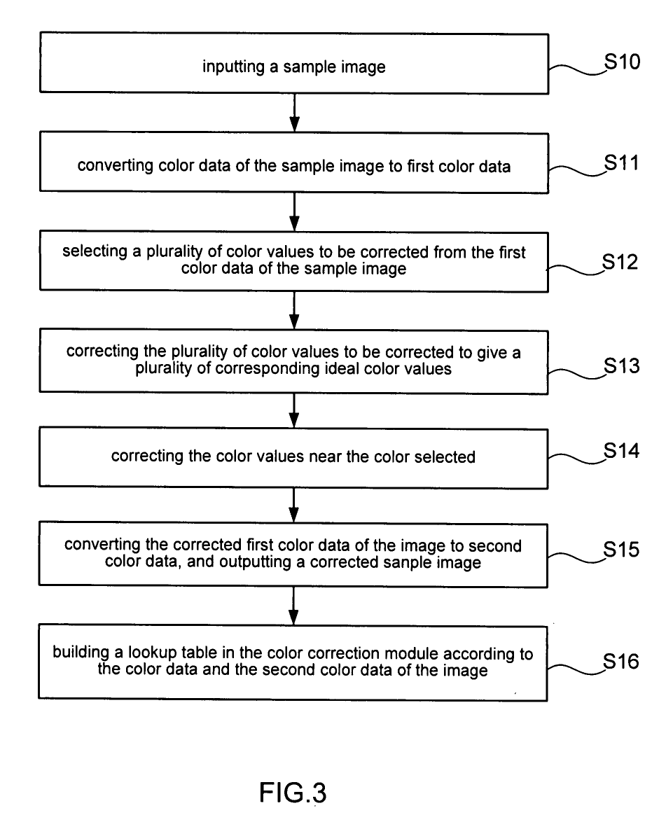

FIG. 3 shows a flowchart of a method for image color correction according to a preferred embodiment of the present invention. As shown in the figure, the method for image color correction according to the present invention first executes the step S10 for inputting a sample image to a first color conversion unit of a color correction module. Next, the step S11 is executed for converting the color data of the sample image to first color data by using the first color conversion unit, and transmitting the first color data to a selection unit. Then, the step S12 is executed for configuring at least one color correction range, and selecting a plurality of color values to be corrected which falls within said at least one color correction range from the first color data of the sample image. Besides, the plurality of color values to be corrected is transmitted to a correction unit.

Afterwards, the step S13 is executed for correcting the plurality of color values to be corrected to the plurality of corresponding ideal color values by using the correction unit. The correction unit first calculates the correction value between each color value to be corrected and the corresponding ideal color value. Then, correct the color value to be corrected to the ideal color value according to the correction value. Thereby, the plurality of color values to be corrected is corrected accordingly, and a plurality of corrected color values is transmitted to a smoothening unit. Next, the step S14 is executed for correcting the color values near the color selected by selection unit. First, the correction color values of the plurality of selected color values are calculated by correction unit. The smoothening unit calculates the relation of correction color values between selected color and neighbor colors. Then, according to the relation of correction color values, correct the plurality of color values neighbor selected colors. Next, smoothen the lightness and color transition there between for giving corrected first color data of the sample image and transmit it to a second color conversion unit.

Next, the step S115 is executed for converting the corrected first color data of the sample image to second color data by using the second color conversion unit, and outputting a corrected image. Then the step S16 is executed for building a lookup table for the color correction module according to the color data of the sample image and the second color data thereof.

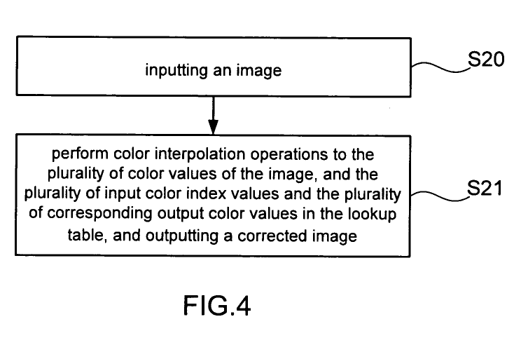

FIG. 4 shows a flowchart of a method for image color correction according to another preferred embodiment of the present invention. The lookup table built according to the method described above stores a plurality of input color index values and a plurality of corresponding output color values. When performing color correction to other images, the lookup table is used directly. The method includes first executing the step S20 for inputting an image to the color correction module. Then the step S21 is executed for finding the plurality of corresponding output color values according to the plurality of color values for the color data of the image to the lookup table or perform color interpolation operations to the plurality of color values of the image, and the plurality of input color index values and the plurality of corresponding output color values in the lookup table by using a color interpolation module. Thereby, the plurality of corresponding output color values of the plurality of color values of the image is given, and a corrected image is outputted according to the plurality of color values.

It is known from the description above that the present invention provides a system for image color correction and a method thereof, which can correct color values to ideal color values or desired color value. In addition, the system for image color correction and the method thereof according to the present invention correct the color values between the corrected and the uncorrected color values, and smoothen the lightness and color transition therebetween so that false-contour problem is not occurred in the image with corrected colors. The system according to the present invention can build a lookup table, and according to which the corresponding color data of an input image can be found. Thereby, complicated correction procedures described above can be reduced, and the speed of color correction is increased as well.

Accordingly, the present invention conforms to the legal requirements owing to its novelty, unobviousness, and utility. However, the foregoing description is only a preferred embodiment of the present invention, not used to limit the scope and range of the present invention. Those equivalent changes or modifications made according to the shape, structure, feature, or spirit described in the claims of the present invention are included in the appended claims of the present invention.

1. A system for image color correction, comprising at least a color correction module, which comprises:
a first color conversion unit, for converting color data of an image to first color data;
a selection unit, for selecting a plurality of color values to be corrected from the first color data;
a correction unit, for correcting the plurality of color values to be corrected to a plurality of corresponding ideal color values for giving a plurality of corrected color values;
a smoothening unit, for correcting a plurality of color values near the color selected by selection unit, and smoothening the lightness and color transition therebetween for giving corrected first color data of the image; and
a second color conversion unit, for converting the corrected first color data of the image to second color data, and outputting a corrected image.

2. The system for image color correction of claim 1, and further comprising a color interpolation module and a lookup table, performs color interpolation operations to the color data of the image according to the lookup table, and outputs the corrected image.

3. The system for image color correction of claim 2, wherein the lookup table is built according to the color data of the color data of a group of sample images and the corresponding second color data.

4. The system for image color correction of claim 2, wherein the lookup table includes a plurality of sets of input color index values and a plurality of corresponding output color values.

5. The system for image color correction of claim 4, wherein each set of the input color index values includes a red value (R), a green value (G), and a blue value (B).

6. The system for image color correction of claim 4, wherein each set of the output color values includes a red value, a green value, and a blue value.

7. The system for image color correction of claim 1, wherein the color data of the image is in the red-green-blue (RGB) color format.

8. The system for image color correction of claim 1, wherein the first color data is in the lightness-chroma-hue (LCh) color format.

9. The system for image color correction of claim 1, wherein the first color data is in the YUV color format.

10. The system for image color correction of claim 1, wherein the first color data is in the XYZ color format.

11. The system for image color correction of claim 1, wherein the first color data is in the Lab color format.

12. The system for image color correction of claim 1, wherein the selection unit further configures at least a color correction range, the plurality of color values falling within the color correction range being a plurality of color values to be corrected.

13. The system for image color correction of claim 1, wherein the correction unit configures a plurality of corresponding ideal color values of the plurality of color values to be corrected, calculates a correction value between each color value to be corrected and the corresponding ideal color value, and corrects the color value to be corrected to give the ideal color value according to the correction value.

14. The system for image color correction of claim 1, wherein the smoothening unit calculates the relation of correction color values between selected color and neighbor colors. Then, according to the relation of correction color values, correct the plurality of color values neighbor selected colors.

15. The system for image color correction of claim 1, wherein the second color data is in the red-green-blue color format.

16. A method for image color correction, comprising:
inputting an image;
converting color data of the image to first color data;
selecting a plurality of color values to be corrected from the first color data of the image;
correcting the plurality of color values to be corrected to give a plurality of corresponding ideal color values for giving a plurality of corrected color values;
correcting a plurality of color values between the plurality of corrected color values between selected color and neighbor colors, and smoothening the lightness and color transition therebetween for giving corrected first color data of the image; and
converting the corrected first color data of the image to second color data, and outputting a corrected image.

17. The method for image color correction of claim 16, and further comprising building a lookup table according to the color data and the second color data of the image.

18. The method for image color correction of claim 16, wherein the color data of the image is in the red-green-blue (RGB) color format.

19. The method for image color correction of claim 16, wherein the first color data is in the lightness-chroma-hue (LCh) color format.

20. The method for image color correction of claim 16, wherein the first color data is in the YUV color format.

21. The method for image color correction of claim 16, wherein the first color data is in the XYZ color format.

22. The method for image color correction of claim 16, wherein the first color data is in the Lab color format.

23. The method for image color correction of claim 16, wherein the step of selecting a plurality of color values to be corrected from the first color data of the image judges if the plurality of color values for the first color data of the image is the plurality of color values to be corrected according to at least a color correction range.

24. The method for image color correction of claim 16, wherein the step of correcting the plurality of color values to be corrected to give a plurality of corresponding ideal color values corrects the color values to be corrected to give the corresponding ideal color values according to a correction value between each color value to be corrected and the corresponding ideal color value.

25. The method for image color correction of claim 16, wherein the step of correcting a plurality of color values between selected color and neighbor colors.

26. The method for image color correction of claim 17, wherein the lookup table includes a plurality of sets of input color index values and a plurality of corresponding output color values.

27. The method for image color correction of claim 26, wherein each set of the input color index values includes a red value, a green value, and a blue value.

28. The method for image color correction of claim 26, wherein each set of the output color values includes a red value, a green value, and a blue value.

29. The method for image color correction of claim 26, wherein the lookup table provides a plurality of color values for an image for performing color interpolation, giving a plurality of corresponding output color values, and outputting a corrected image according to the plurality of output color values.

30. A method for image color correction, comprising:
inputting an image to a lookup table according to the plurality of color values for color data of the image for inputting to the lookup table and finding out a plurality of corresponding output color values; and
outputting a corrected image according to the plurality of output color values.

31. The method for image color correction of claim 30, wherein further perform color interpolation operations to the plurality of color values of the image according to the lookup table for giving a plurality of corresponding output color values and outputting a corrected image according to the plurality of output color values.
